(19) United States
(12) Patent Application Publication
(10) Pub. No.: US 2007/0187577 A1
(43) Pub. Date: Aug. 16, 2007

(54) Photoswitch

(76) Inventor: Te-Shu Kao, Taichung City (TW)

Correspondence Address: NIXON PEABODY, LLP, 401 9TH STREET, NW, SUITE 900, WASHINGTON, DC, 20004-2128, US

(21) Appl. No.: 11/350,842

(22) Filed: Feb. 10, 2006

(51) Int. Cl. H03K 17/78; H01H 47/24

(52) U.S. Cl. 250/214 SW; 307/117

(57) ABSTRACT

A photoswitch includes first and second signal sources for outputting first and second input signals that switch between high and low logic states according to intensity of ambient light, and a latch circuit having set and reset nodes coupled electrically and respectively to the first and second signal sources, and an output node coupled electrically to a switch circuit. When the first and second input signals respectively have the high and low logic states, the output node drives the switch circuit to an on state. When the first and second input signals respectively have the low and high logic states, the output node drives the switch circuit to an off state. When the first and second input signals both have the low logic state, the output node maintains the switch circuit at a current one of the on and off states.

### BACKGROUND OF THE INVENTION

1. Field of the Invention

The invention relates to a switch, more particularly to a photo switch that turns on and off according to intensity of ambient light.

2. Description of the Related Art

As shown in FIG. 1 and FIG. 2, a conventional photoswitch 10, which turns on and off according to intensity of ambient light, is normally used in a household night lamp 1 for switching the household night lamp 1 on and off automatically. The conventional photoswitch 10 can also be applied to other devices, such as a street lamp, a motor, a speaker, etc.

The conventional photoswitch 10 includes a signal source 11 and a switch circuit 12.

The signal source 11 outputs an input signal 110 that switches between high and low logic states according to the intensity of the ambient light. The signal source 11 include a reference signal generator 13 for generating a reference signal 130, a light sensor 14 for generating a comparison signal 140 that varies with the intensity of the ambient light, and a comparator 15. The reference signal generator 13 is in the form of a first voltage divider including a pair of resistors (R1), (R2) connected in series. The reference signal 130 is node voltage obtained at a junction of the resistors (R1), (R2) of the first voltage divider. The light sensor 14 is in the form of a second voltage divider including a pair of resistors (R3) (R4) connected in series, where the resistor (R4) is a light-sensitive resistor (cds). The comparison signal 140 is node voltage obtained at a Junction of the resistors (R3), (R4) of the second voltage divider. The comparator 15 is in the form of an operational amplifier that is connected electrically to the reference signal generator 13 and the light sensor 14, that compares the first reference signal 130 and the first comparison signal 140, and that outputs the input signal 110 to the switch circuit 12.

The switch circuit 12 includes a transistor (Q1) and a relay (Relay) connected in series. The transistor (Q1) receives the input signal 110 from the comparator 15 of the signal source 11, and drives the relay (Relay) between on and off states according to the input signal 110 received from the comparator 15.

Under ideal conditions, resistance of the light-sensitive resistor (cds) increases as the intensity of ambient light decreases. According to voltage division, the comparison signal 140 increases as a result. When the comparison signal 140 is larger than the reference signal 130, the input signal 110 outputted by the signal source 11 has the high logic state, and the switch circuit 12 is thus at the on state.

However, this is not what happens in reality. When the switch circuit 12 is connected electrically to a light-emitting component 16, it is unavoidable that the light-emitting component 16 is in the vicinity of the light-sensitive resistor (cds). When the switch circuit 12 is at the on state, the light-emitting component 16 is activated. The light emitted by the light-emitting component 16 causes the intensity of the ambient light to increase, and affects the light-sensitive resistor (cds) such that the resistance of the light-sensitive resistor (cds) decreases, which can result in switching of the switch circuit 12 to the off state. Since the light-emitting component 16 is deactivated when the switch circuit 12 is at the off state, the intensity of the ambient light is once again decreased such that the resistance of the light-sensitive resistor (cds) increases, thereby switching the switch circuit 12 to the on state, and resulting in activation of the light-emitting component 16. This phenomenon occurs repeatedly, causing the light-emitting component 16 to fluctuate between activated and deactivated states. Not only is the performance of the house hold night lamp 1 degraded, but the light-emitting component 16 is also easily and quickly damaged.

In order to minimize fluctuation of light-emitting components, it is normally desired to choose a light-emitting component 16 with a relatively low candela when the conventional photoswitch 10 is applied to a household night lamp 1 (as shown in FIG. 1), or to install the light-sensitive resistor (cds) deeper in the night lamp 1. However, since the light-emitting component 16 is required to have high candela when the conventional photoswitch 10 is applied to a street lamp (not shown), the light-sensitive resistor (cds) is installed at the back of the light-emitting component 16 to minimize the fluctuations of the light-emitting component 16.

If the conventional photoswitch 10 is to be applied to an indoor lamp, high candela of the light-emitting component 16 is required, and installation of the light-sensitive resistor (cds) at the back of the light-emitting component 16 would create difficulty during implementation.

### SUMMARY OF THE INVENTION

Therefore, the object of the present invention is to provide a photoswitch capable of providing stable on/off switching.

According to the present invention, there is provided a photoswitch that includes a first signal source for outputting a first input signal that switches between high and low logic states according to intensity of ambient light received by the first signal source, a second signal source for outputting a second input signal that switches between high and low logic states according to intensity of ambient light received by the second signal source, a switch circuit, and a latch circuit. The latch circuit has a set node coupled electrically to the first signal source for receiving the first input signal, a reset node coupled electrically to the second signal source for receiving the second input signal, and an output node coupled electrically to the switch circuit for driving the switch circuit between on and off states. When the first input signal has the high logic state, and the second input signal has the low logic state, the output node of the latch circuit drives the switch circuit to the on state. When the first input signal has the low logic state, and the second input signal has the high logic state, the output node of the latch circuit drives the switch circuit to the off state. When both of the first and second input signals have the low logic state, the output node of the latch circuit maintains the switch circuit at a current one of the on and off states.

### BRIEF DESCRIPTION OF DRAWINGS

Other features and advantages of the present invention will become apparent in the following detailed description of the preferred embodiment with reference to the accompanying drawings, of which:

FIG. 1 is a perspective view of a night lamp having a conventional photoswitch applied thereto;

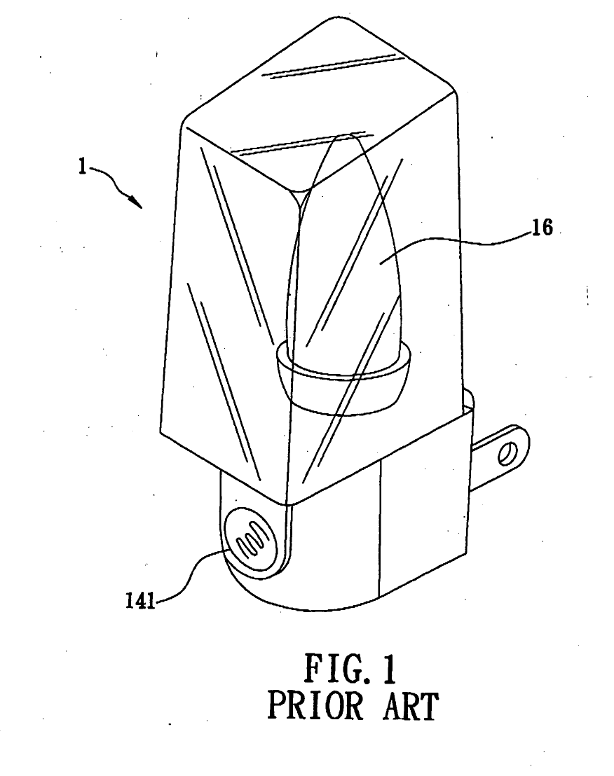

FIG. 2 is a schematic electrical circuit diagram of the conventional photoswitch; and

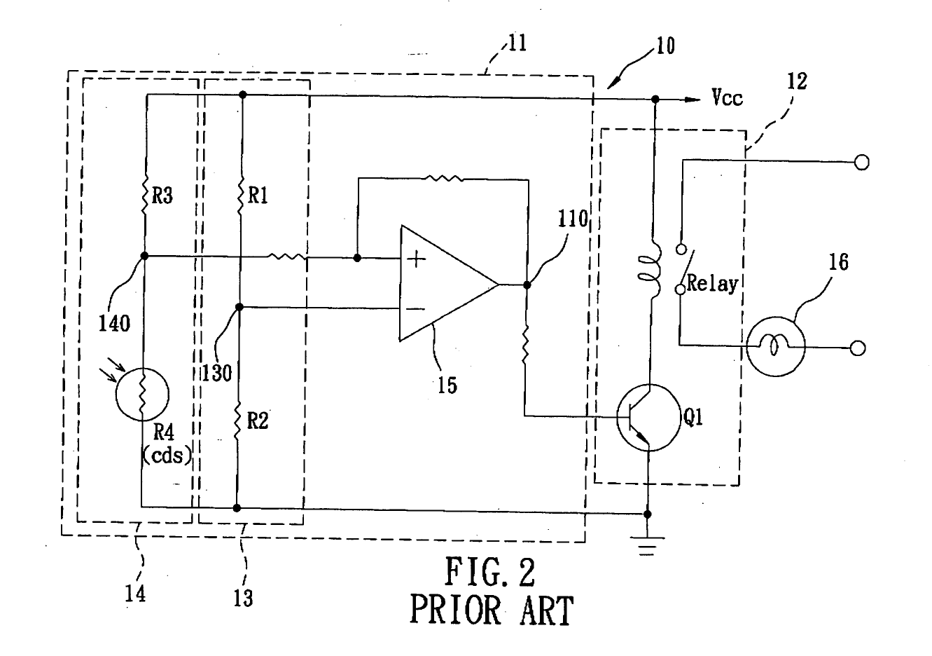

FIG. 3 is a schematic electrical circuit diagram of the preferred embodiment of a photoswitch according to the present invention.

### DETAILED DESCRIPTION OF THE PREFERRED EMBODIMENT

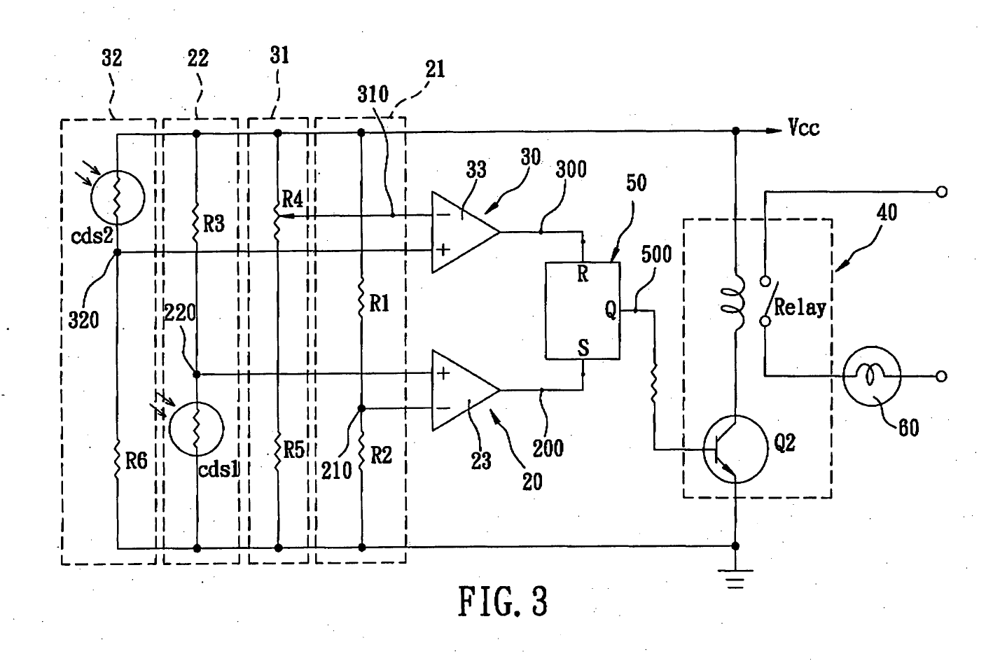

As shown in FIG. 3, the preferred embodiment of a photoswitch according to the present invention includes a first signal source 20, a second signal source 30, a switch circuit 40, and a latch circuit 50.

The first signal source 20 outputs a first input signal 200 that switches between high and low logic states according to intensity of ambient light received by the first signal source 20. The first signal source 20 includes a first reference signal generator 21, a first light sensor 22, and a first comparator 23. The first reference signal generator 21 includes a pair of resistors (R1), (R2) connected in series, constituting a first voltage divider, and generating a first reference signal 210 at a junction of the resistors (R1), (R2). The first reference signal 210 corresponds to a low brightness setting in this embodiment. The first light sensor 22 includes a resistor (R3) and a first light-sensitive resistor (cds1) connected in series, and generates a first comparison signal 220 at a junction of the resistors (R3), (cds1). The first comparison signal 220 varies according to the intensity of the ambient light received by the first light sensor 22. The first comparator 23 is connected electrically to the first reference signal generator 21 and the first light sensor 22, and compares the first reference signal 210 and the first comparison signal 220. In this embodiment, the first comparator 23 is in the form of an operational amplifier.

The second signal source 30 outputs a second input signal 300 that switches between high and low logic states according to intensity of ambient light received by the second signal source 30. The second signal source 30 includes a second reference signal generator 31, a second light sensor 32, and a second comparator 33. The second reference signal generator 31 includes a variable resistor (R4) and a fixed resistor (R5) connected in series, constituting a second voltage divider, and generating a second, reference signal 310. The variable resistor (R4) has a center tap connected to the second comparator 33 and from which the second reference signal 310 is obtained.

The second reference signal 310 corresponds to a high brightness setting. Due to the variable resistor (R4), the second reference signal 310 is adjustable so as to suit a desired brightness setting. The second light sensor 32 includes a resistor (R6) and a second light-sensitive resistor (cds2) connected in series, and generates a second comparison signal 320 at a junction of the resistors (R6), (cds2). The second comparison signal 330 varies according to the intensity of the ambient light received by the second light sensor 32. The second comparator 33 is connected electrically to the second reference signal generator 31 and the second light sensor 32, and compares the second reference signal 310 and the second comparison signal 320. In this embodiment, the second comparator 33 is in the form of an operational amplifier.

The switch circuit 40 includes a transistor (Q2) and a relay (Relay) connected in series. The transistor (Q2) is connected electrically to the latch circuit 50. In this embodiment, the switch circuit 40 is connected electrically to a light bulb 60.

The latch circuit 50 has a set node (S), a reset node (R), and an output node (Q). The set node (S) is coupled electrically to the first comparator 23 of the first signal source 20 for receiving the first input signal 200 therefrom. The reset node (R) is coupled electrically to the second comparator 33 of the second signal source 30 for receiving the second input signal 300 therefrom. Based on the first and second input signals 200, 300, the latch circuit 50 generates a control signal 500 that switches between high and low logic states for driving the switch circuit 40. The control signal 500 is outputted through the output node (Q), which is coupled electrically to the switch circuit 40 for driving the switch circuit 40 between on and off states according to the control signal 500. In this embodiment, the latch circuit 50 includes a flip-flop having the set, reset and output nodes (S), (R), (Q). More particularly, the flip-flop is a set-reset flip-flop.

In use, when the first input signal 200 has the high logic state and the second input signal 300 has the low logic state, the control signal 500 has the high logic state, and the output node (Q) drives the switch circuit 40 to the on state. When the first input signal 200 has the low logic state and the second input signal 300 has the high logic state, the control signal 500 has the low logic state, and the output node (Q) of the latch circuit 50 drives the switch circuit 40 to the off state. When both of the first and second input signals 200, 300 have the low logic state, the control signal 500 maintains a current one of the high and low logic states, and the output node (Q) of the latch circuit 50 maintains the switch circuit 40 at a current one of the on and off states.

When the intensity of the ambient light decreases, resistances of the first and second light-sensitive resistors (cds1), (cds2) increase. Since the voltage across the first light-sensitive resistor (cds1) is compared to the low brightness setting, the increase in the resistance of the first light-sensitive resistor (cds1) can cause the first comparison signal 220 to be higher than the first reference signal 210 such that the first input signal 200 has the high logic state. Since the voltage across the resistor (R6) is compared to the high brightness setting, the second comparison signal 320 is lower than the second reference signal 310. Therefore, the second input signal 300 has the low logic state. As a result, the output node (Q) of the latch circuit 50 drives the switch circuit 40 to the on state such that the light bulb 60 is lit.

At the instant the light bulb 60 is lit, the intensity of the ambient light increases slightly such that the resistances of the first and second light-sensitive resistors (cds1), (cds2) decrease. The decrease in the resistance of the first light-sensitive resistor (cds1) can cause the first comparison signal 220 to be lower than the first reference signal 210 such that the first input signal 200 has the low logic state. However, the decrease in the resistance of the second light-sensitive resistor (cds2) is not enough to cause the second comparison signal 320 to be higher than the second reference signal 310. Thus, the second input signal 300 maintains the low logic state. As a result, the output node (Q) of the latch circuit 50 maintains the switch circuit 40 at the current one of the on and off states, which is the on state in this case. It is shown that the switch circuit 40 will not be driven into the off state upon lighting of the light bulb 60.

When the intensity of the ambient light increases for a substantial extent (i.e. not only due to lighting of the light bulb 60), the resistance of the second light-sensitive resistor (cds2) decreases substantially such that the second comparison signal 320 becomes higher than the second reference signal 310, thus causing the second input signal 300 to have the high logic state. As a result, the output node (Q) of the latch circuit 50 drives the switch circuit 40 to the off state, and the light bulb 60 is extinguished.

In sum, the photoswitch according to the present invention utilizes the first and second signal sources 20, 30, and the latch circuit 50 to maintain the switch circuit 40 at the current one of the on and off states when the intensity of the ambient light changes within a relatively small range. Thus, the photoswitch according to the present invention has the advantage of providing stable on/off switching for the switch circuit 40 thereof.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A photoswitch comprising:
a first signal source for outputting a first input signal that switches between high and low logic states according to intensity of ambient light received by said first signal source;
a second signal source for outputting a second input signal that switches between high and low logic states according to intensity of ambient light received by said second signal source;
a switch circuit; and
a latch circuit having
a set node coupled electrically to said first signal source for receiving the first input signal,
a reset node coupled electrically to said second signal source for receiving the second input signal, and
an output node coupled electrically to said switch circuit for driving said switch circuit between on and off states,
wherein, when the first input signal has the high logic state, and the second input signal has the low logic state, said output node of said latch circuit drives said switch circuit to the on state,
wherein, when the first input signal has the low logic state, and the second input signal has the high logic state, said output node of said latch circuit drives said switch circuit to the off state, and
wherein, when both of the first and second input signals have the low logic state, said output node of said latch circuit maintains said switch circuit at a current one of the on and off states.

2. The photoswitch as claimed in claim 1, wherein:
said first signal source includes a first reference signal generator for generating a first reference signal, a first light sensor for generating a first comparison signal that varies according to the intensity of the ambient light received by said first light sensor, and a first comparator that is connected electrically to said first reference signal generator and said first light sensor, that compares the first reference signal and the first comparison signal, and that is further connected electrically to said set node of said latch circuit so as to provide the first input signal to said set node; and
said second signal source includes a second reference signal generator for generating a second reference signal, a second light sensor for generating a second comparison signal that varies according to the intensity of the ambient light received by said second light sensor, and a second comparator that is connected electrically to said second reference signal generator and said second light sensor, that compares the second reference signal and the second comparison signal, and that is further connected electrically to said reset node of said latch circuit so as to provide the second input signal to said reset node.

3. The photoswitch as claimed in claim 2, wherein:
said first reference signal generator includes a first voltage divider, and the first reference signal corresponds to a low brightness setting; and
said second reference signal generator includes a second voltage divider, and the second reference signal corresponds to a high brightness setting.

4. The photoswitch as claimed in claim 3, wherein said second reference signal generator includes a variable resistor and a fixed resistor connected in series, the second reference signal being adjustable, said variable resistor having a center tap connected to said second comparator.

5. The photoswitch as claimed in claim 3, wherein each of said first and second light sensors includes a pair of resistors connected in series, one of said resistors of each of said first and second light sensors being a light-sensitive resistor.

6. The photoswitch as claimed in claim 1, wherein said latch circuit includes a flip-flop having said set, reset and output nodes.

7. The photoswitch as claimed in claim 6, wherein said flip-flop is a set-reset flip-flop.
